(19) United States
(12) Patent Application Publication
(10) Pub. No.: US 2013/0003932 A1
(43) Pub. Date: Jan. 3, 2013

(54) RADIOGRAPHIC IMAGE CAPTURE DEVICE, BATTERY UNIT, ELECTRICITY SUPPLY UNIT, RADIOGRAPHIC IMAGE CAPTURE SYSTEM AND COMPUTER READABLE MEDIUM

(75) Inventor: Naoyuki NISHINO, Kanagawa (JP)

(73) Assignee: FUJIFILM CORPORATION, Tokyo (JP)

(21) Appl. No.: 13/472,894

(22) Filed: May 16, 2012

(30) Foreign Application Priority Data
Jul. 1, 2011 (JP) 2011-147724

(51) Int. Cl. H05G 1/64; H01M 10/50; H05K 7/20

(52) U.S. Cl. 378/91; 361/688; 429/120

(57) ABSTRACT

A radiographic image capture device is equipped with a radiographic detector and a retention portion. The radiographic detector acquires a radiographic image in accordance with incident radiation, and has a heat-generating body inside. The retention portion is provided so as to be in contact with the heat-generating body of the radiographic detector, detachably retains a power supply portion, and is thermally conductive.

### CROSS-REFERENCE TO RELATED APPLICATIONS

This application claims priority under 35 USC 119 from Japanese Patent Application No. 2011-147724 filed on Jul. 1, 2011, the disclosure of which is incorporated by reference herein.

### BACKGROUND OF THE INVENTION

1. Field of the Invention

The present invention relates to a radiographic image capture device, a battery unit, an electricity supply unit, a radiographic image capture system and a computer readable medium storing a program to be executed at the radiographic image capture device. The present invention particularly relates to a radiographic image capture device equipped with a retention portion that detachably retains a battery unit, the battery unit and an electricity supply unit that are mountable and detachable at the retention portion of the radiographic image capture device, and a radiographic image capture system and a computer readable medium storing a program to be executed at the radiographic image capture device.

2. Description of the Related Art

Heretofore, it has been desirable for a portable radiographic image capture device to have an enclosed form, with a view to preventing contamination. For thermal discharge of heat generated in a radiographic detector of this radiographic image capture device, discharging heat inside a casing is sufficient when capturing still images. However, generated heat amounts are large when capturing video images, and there are concerns that simply discharging heat inside the casing is insufficient. Accordingly, various techniques for discharging heat have been applied to portable radiographic image capture devices.

For example, Japanese Patent Application Laid-Open (JP-A) No. 2007-222604 recites a technology for a radiographic image capture device which includes a retention portion that retains a radiographic detector and a connection mechanism that enables mounting and detachment of the radiographic detector at the retention portion. The connection mechanism both mechanically connects the radiographic detector with the retention portion and transfers heat between the radiographic detector and the retention portion. In the technology recited in JP-A No. 2007-222604, heat generated by a heat-generating body such as the radiographic detector may be dissipated due to electronic circuits of the radiation detector in the radiographic image capture device being thermally connected with a frame.

JP-A No. 2005-181922 discloses, for a radiographic image capture device which includes a casing that encloses a radiographic detector and a cooling unit that suppresses temperature rises inside the casing, a technology in which the cooling unit is mountable and detachable at the exterior of the casing. In the technology recited in JP-A No. 2005-181922, even when situations arise in which large amounts of heat dissipation are necessary, because the cooling unit is mounted to the radiographic image capture device, heat dissipation from the casing is possible.

With a method of thermally connecting electronic circuits of a radiographic detector in a radiographic image capture device with a frame, depending on a position of arrangement of the radiographic image capture device, thermal connection with the frame so as to dissipate heat generated by the radiographic detector may not necessarily be possible. Moreover, the device may become heavier and the greatest advantage of a portable radiographic image capture device, ease of repositioning, may be weakened.

With a method of mounting a cooling unit to a radiographic image capture device, replacement of the cooling unit is not necessarily simple, and the advantages of a portable radiographic image capture device in terms of convenience may be weakened.

### SUMMARY OF THE INVENTION

The present invention has been made in view of the above circumstances and provides a radiographic image capture device, a battery unit, an electricity supply unit, a radiographic image capture system and a computer readable medium storing a program to be executed at the radiographic image capture device.

According to a first aspect of the present invention, there is provided a radiographic image capture device including: a radiographic detector that acquires a radiographic image in accordance with incident radiation and that includes a heat-generating body at an inner part thereof; and a retention portion that is provided so as to be in contact with the heat-generating body of the radiographic detector, that detachably retains a power supply portion, and that is thermally conductive.

According to another aspect of the present invention, there is provided a battery unit including: a retained portion that is retained at a retention portion of a radiographic image capture device including a radiographic detector that acquires a radiographic image in accordance with incident radiation and that includes a heat-generating body in an inner part thereof, and including the retention portion, which is provided so as to be in contact with the heat-generating body of the radiographic detector, which detachably retains a power supply portion, and which is thermally conductive; the power supply portion, which supplies electric power to the radiographic detector when the retained portion is retained at the retention portion; and a cooling section that cools the radiographic image capture device when the retained portion is retained at the retention portion.

According to another aspect of the present invention, there is provided an electricity supply unit including: a retained portion that is retained at a retention portion of a radiographic image capture device including a radiographic detector that acquires a radiographic image in accordance with incident radiation and that includes a heat-generating body at an inner part thereof, and including the retention portion, which is provided so as to be in contact with the heat-generating body of the radiographic detector, which detachably retains a power supply portion, and which is thermally conductive; a power cable that supplies electric power to the radiographic detector if the retained portion is retained at the retention portion; and a cooling section that cools the radiographic image capture device if the retained portion is retained at the retention portion.

According to another aspect of the present invention, there is provided a radiographic image capture system including: the radiographic image capture device according to the first aspect; and a battery unit including: a retained portion that is retained at a retention portion of a radiographic image capture device including a radiographic detector that acquires a radiographic image in accordance with incident radiation and that includes a heat-generating body at an inner part thereof, and including the retention portion, which is provided so as to be in contact with the heat-generating body of the radiographic detector, which detachably retains a power supply portion, and which is thermally conductive; the power supply portion, which supplies electric power to the radiographic detector if the retained portion is retained at the retention portion; and a cooling section that cools the radiographic image capture device if the retained portion is retained at the retention portion.

According to another aspect of the present invention, there is provided a radiographic image capture system including: the radiographic image capture device according to the first aspect; and an electricity supply unit including: a retained portion that is retained at a retention portion of a radiographic image capture device including a radiographic detector that acquires a radiographic image in accordance with incident radiation and that includes a heat-generating body at an inner part thereof, and including the retention portion, which is provided so as to be in contact with the heat-generating body of the radiographic detector, which detachably retains a power supply portion, and which is thermally conductive; a power cable that supplies electric power to the radiographic detector if the retained portion is retained at the retention portion; and a cooling section that cools the radiographic image capture device if the retained portion is retained at the retention portion.

According to another aspect of the present invention, there is provided a computer readable medium storing a program causing a computer to execute a processing including: detecting whether or not an electricity supply unit is retained at a retention portion of a radiographic image capture device, wherein the radiographic image capture device includes a radiographic detector that acquires a radiographic image in accordance with incident radiation and that includes a heat-generating body at an inner part thereof, and includes the retention portion, which is provided so as to be in contact with the heat-generating body of the radiographic detector, which detachably retains a power supply portion, and which is thermally conductive, and wherein the electricity supply unit includes a power cable that supplies electric power to the radiographic detector in a state in which the electricity supply unit is retained at the retention portion; if it is detected that the electricity supply unit is retained at the retention portion, allowing continuous imaging; and if it is not detected that the electricity supply unit is retained at the retention portion, prohibiting continuous imaging.

### BRIEF DESCRIPTION OF THE DRAWINGS

Preferred embodiments of the present invention will be described in detail based on the following figures, wherein:

FIG. 1 is a block diagram illustrating structure of a radiographic image capture system in accordance with an exemplary embodiment.

FIG. 2 is a schematic perspective view illustrating structure of an electronic cassette and a battery unit in accordance with a first exemplary embodiment.

FIG. 3 is a side sectional view, taken in direction Y of FIG. 2, of the electronic cassette in accordance with the first exemplary embodiment.

FIG. 4 is a schematic plan view of the electronic cassette in accordance with the first exemplary embodiment.

FIG. 5 is a block diagram (a partial circuit diagram) showing principal structures of electrical systems of the electronic cassette and battery unit in accordance with the exemplary embodiment, and a method of mounting of the battery unit to the electronic cassette.

FIG. 6 is a schematic plan view of another example of the electronic cassette in accordance with the first exemplary embodiment.

FIG. 7 is a schematic perspective view showing structure of an electronic cassette and a battery unit in accordance with a second exemplary embodiment.

FIG. 8A is a schematic perspective view showing structure of an electronic cassette and an electricity supply unit in accordance with a third exemplary embodiment, showing a state in which a power cable is connected to the electricity supply unit.

FIG. 8B is a schematic perspective view showing structure of the electronic cassette and electricity supply unit in accordance with the third exemplary embodiment, showing a state in which the power cable is not connected to the electricity supply unit.

FIG. 9A is a schematic perspective view showing structure of an electronic cassette and an electricity supply unit in accordance with a fourth exemplary embodiment.

FIG. 9B is a schematic side view for describing a cooling mechanism of the electronic cassette and electricity supply unit in accordance with the fourth exemplary embodiment.

FIG. 10 is a schematic plan view of an electronic cassette in accordance with a fifth exemplary embodiment.

FIG. 11 is a schematic perspective view illustrating structure of an electronic cassette and an electricity supply unit in accordance with the fifth exemplary embodiment.

FIG. 12 is a schematic perspective view illustrating structure of an electronic cassette and a battery unit in accordance with a sixth exemplary embodiment.

FIG. 13 is a schematic plan view of an electronic cassette in accordance with the sixth exemplary embodiment.

FIG. 14 is a schematic perspective view showing structure of an electronic cassette and a battery unit in accordance with a seventh exemplary embodiment.

FIG. 15 is a flow chart showing a flow of processing of a continuous imaging allowability control processing program in accordance with an eighth embodiment.

FIG. 16 is a block diagram showing structure of a radiographic image capture system in accordance with a ninth embodiment.

### DETAILED DESCRIPTION OF THE INVENTION

Herebelow, modes for embodying the present invention are described in detail with reference to the attached drawings. Herein, an example is described in which the present invention is applied to a radiographic image capture system that performs capturing of radiographic images using a portable radiographic image capture device (hereinafter referred to as an electronic cassette).

### First Exemplary Embodiment

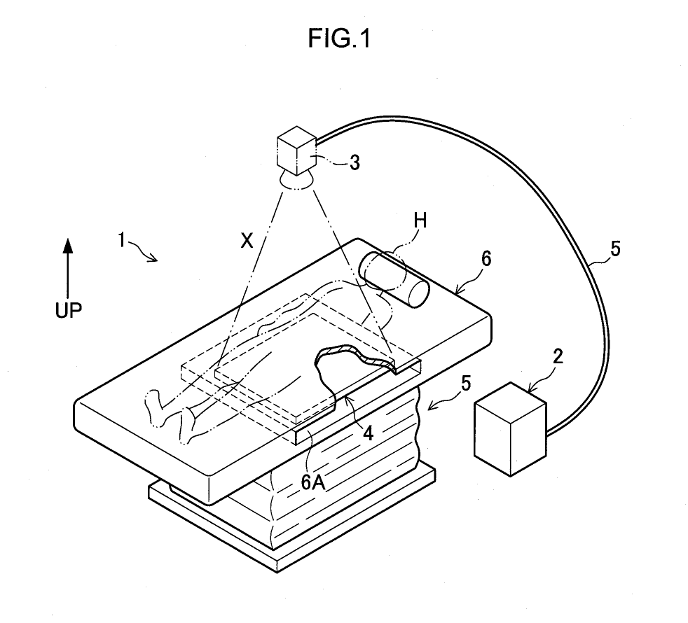

FIG. 1 is a schematic structural diagram of a radiographic image capture system 1 in accordance with a first exemplary embodiment.

As shown in FIG. 1, the radiographic image capture system 1 according to the first exemplary embodiment is placed in an imaging room (hereinafter referred to as an x-ray room) for capturing images of radiation (in the present exemplary embodiment, x-rays). The radiographic image capture system 1 is provided with an imaging control device (hereinafter referred to as a console) 2, a radiation generation device 3 and an electronic cassette 4.

The console 2 is connected with the radiation generation device 3 via a communications cable 5. When the radiation generation device 3 is to expose radiation X at a subject H, who is laid on an imaging platform 6, in accordance with signals from an unillustrated exposure switch, the console 2 receives exposure synchronization signals from the radiation generation device 3 and acquires an exposure timing. At this time, even after the console 2 has received the exposure synchronization signals from the radiation generation device 3, the console 2 may monitor the state of the exposure switch. The console 2 controls the electronic cassette 4, matching the exposure timing, and acquires image data.

The electronic cassette 4 generates image data representing a radiation image from the incident radiation X. The generated image data is transmitted to the console 2 by wireless communications. The console 2 is constituted to be capable of wireless communications with the electronic cassette 4, communicates by a pre-specified wireless communications system, and applies various controls to the electronic cassette 4 by transmitting control signals.

The imaging platform 6 is provided with a cassette retention portion 6A, which is formed in a recess shape such that the electronic cassette 4 can be retained thereinside. Radiation images are imaged in a state in which the electronic cassette 4 is retained in the cassette retention portion 6A.

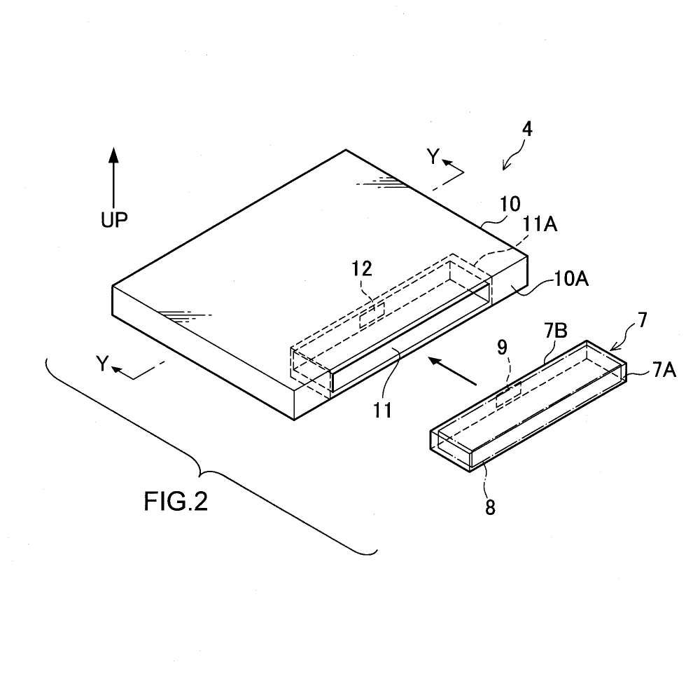

FIG. 2 is a schematic perspective view illustrating structure of the electronic cassette 4 and a battery unit 7 in accordance with the present exemplary embodiment.

As shown in FIG. 2, the electronic cassette 4 according to the present exemplary embodiment is provided with a casing 10, and a radiation detector (a radiation detector 13 which is described below) and such are accommodated inside the casing 10. A battery retention portion 11 is provided at a side face 10A of the casing 10. The battery retention portion 11 is formed in a recess shape for retaining the battery unit 7 thereinside. The battery retention portion 11 is provided with a heat conduction portion 11A, which is formed of a material with excellent thermal conductivity. The battery retention portion 11 is in contact with heat-generating bodies such as the battery unit 7 and the electronic cassette 4, via the heat conduction portion 11A. A material forming the heat conduction portion 11A is, for example, copper, gold, silver, aluminum, a magnesium alloy or the like. A connection portion 12 is provided at an inner surface of the battery retention portion 11. The connection portion 12 includes a connection terminal for connection of the battery unit 7.

In the present exemplary embodiment, the battery unit 7 is provided with a power supply source 8, and is constituted to be mountable and detachable at the electronic cassette 4. The battery unit 7 is a unit that supplies electric power from the power supply source 8 to the electronic cassette 4. The battery unit 7 is formed in substantially the same shape as the shape of the interior of the battery retention portion 11, and is provided with a casing 7A that may be accommodated inside the battery retention portion 11. The power supply source 8 or the like for supplying power to the electronic cassette 4 is accommodated inside the casing 7A. A connection portion 9 is provided at a side face 7B of the casing 7A. The connection portion 9 includes a connection terminal for connection with the connection portion 12 of the electronic cassette 4. In the state in which the battery unit 7 is retained in the battery retention portion 11, the connection portion 9 of the battery unit 7 is connected to the connection portion 12 of the electronic cassette 4. Therefore, power is supplied from the battery unit 7 to the electronic cassette 4 via the respective connection portions 9 and 12.

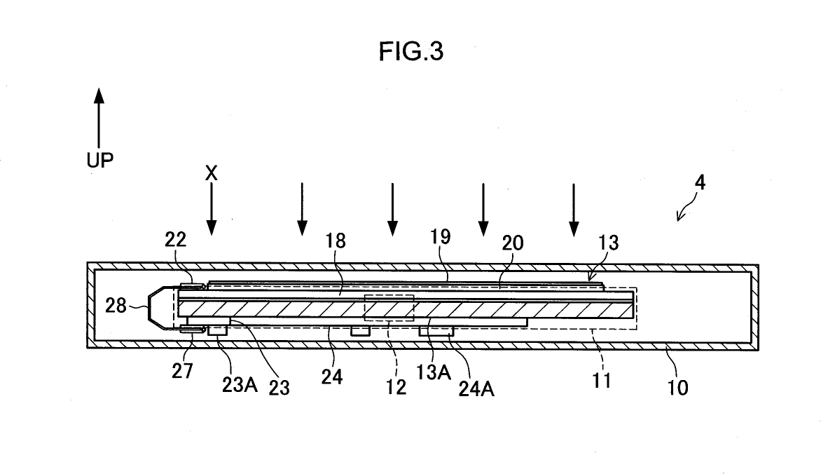

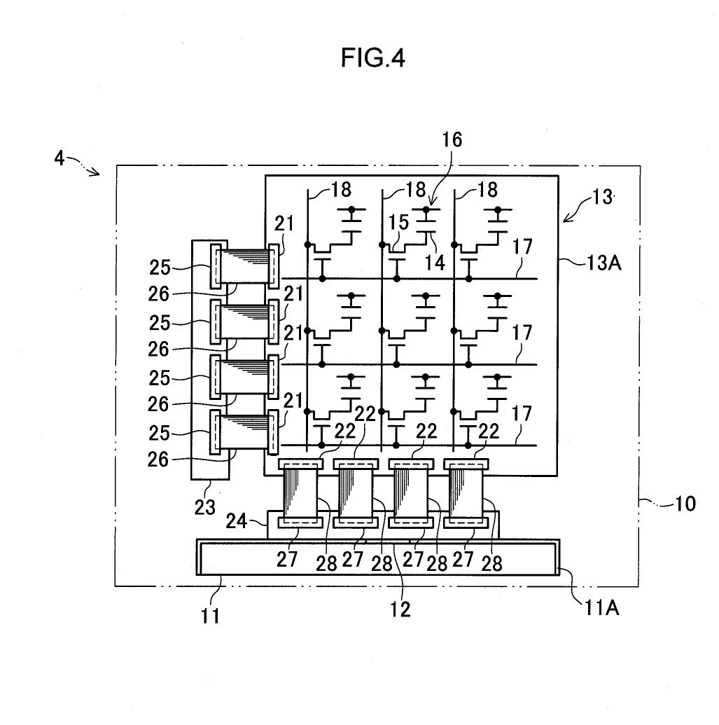

FIG. 3 is a side sectional view, taken along a section line Y-Y in FIG. 2, of the electronic cassette 4 according to the present exemplary embodiment. FIG. 4 is a schematic plan view of the interior of the electronic cassette 4 according to the present exemplary embodiment. In FIG. 4, for convenience, a scanning control board 23 and a signal processing board 24 are shown at the sides of the radiation detector 13. In practice however, as shown in FIG. 3, the scanning control board 23 and the signal processing board 24 are disposed at the rear face of the radiation detector 13.

As shown in FIG. 3 and FIG. 4, at the electronic cassette 4, a board 13A for mounting of the radiation detector 13 is accommodated inside the casing 10, and the radiation detector 13 is provided at a front face of the board 13A. Numerous pixels 16 are disposed in a two-dimensional pattern at the radiation detector 13. Each pixel 16 is structured to include a sensor portion 14 that receives light and accumulates charges, and a thin film transistor (TFT) switch 15 for reading out the charges accumulated in the sensor portion 14.

Plural scan lines 17 and plural signal lines 18 are provided mutually orthogonally in the radiation detector 13. The scan lines 17 are for turning the above-mentioned TFT switches 15 on and off. The signal lines 18 are for reading out the charges accumulated in the sensor portions 14.

At the radiation detector 13, the irradiated radiation X is converted to light by a scintillator 19 formed of GOS, CsI (Tl) or the like. The scintillator 19 includes a light-blocking body 20 for preventing the generated light from leaking to the outside.

Plural connectors 21 for wire connection are arrayed at one end side of the scan lines 17 of the radiation detector 13, and plural connectors 22 are arrayed at one end side of the signal lines 18. The scan lines 17 are connected to the connectors 21, and the signal lines 18 are connected to the connectors 22.

The scanning control board 23 and the signal processing board 24 are provided in the present exemplary embodiment. A scan signal control circuit 23A is mounted at the scanning control board 23 and a signal detection circuit 24A is mounted at the signal processing board 24. The scan signal control circuit 23A controls electronic signals flowing through the scan lines 17, and the signal detection circuit 24A applies signal processing to electronic signals flowing in the signal lines 18. Boards of the scanning control board 23 and the signal processing board 24 are each formed of an insulator.

Connectors 25 are provided at the scan signal control circuit 23A. Each connector 25 is electrically connected to one end of a flexible cable 26. The other ends of the flexible cables 26 are connected to the connectors 21. The scan signal control circuit 23A outputs control signals for turning the TFT switches 15 on and off to the scan lines 17.

Plural connectors 27 are provided at the signal detection circuit 24A. Each connector 27 is electrically connected to one end of a flexible cable 28. The other ends of the flexible cables 28 are connected to the connectors 22. For each signal line 18, an amplification circuit that amplifies inputted electronic signals is incorporated. According to this constitution, the signal detection circuit 24A amplifies electronic signals inputted by the signal lines 18 with the amplification circuits and detects the electronic signals. Thus, the signal detection circuit 24A detects charge amounts that have been accumulated in the sensor portions 14 to serve as information of the pixels 16 constituting an image.

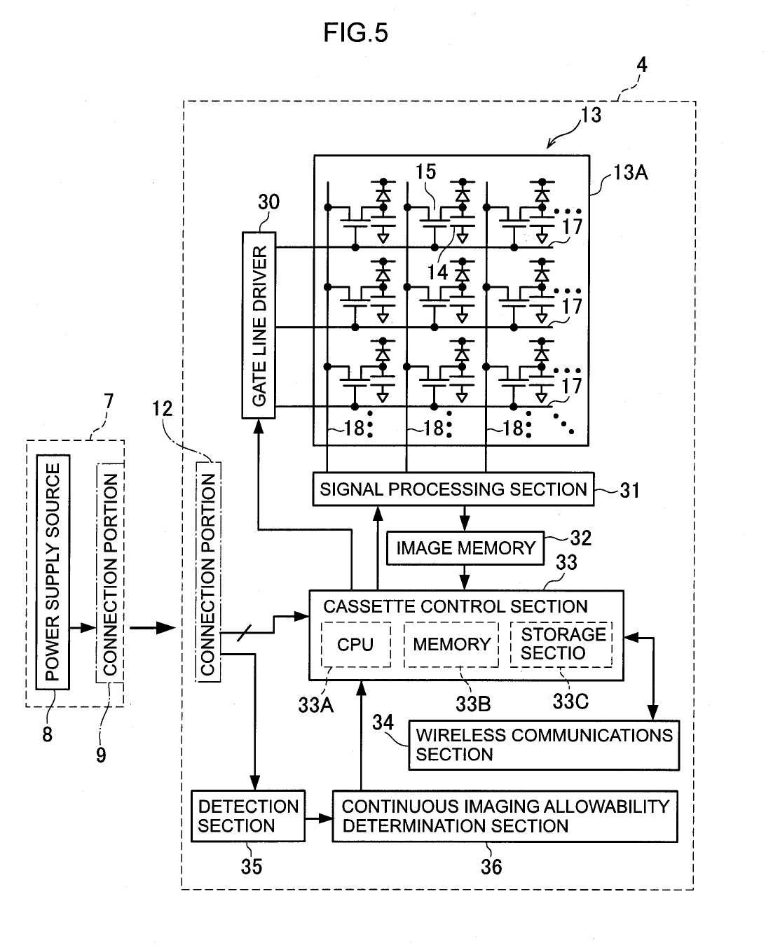

FIG. 5 is a diagram showing principal structures of electrical systems of the electronic cassette 4 and the battery unit 7 according to the present exemplary embodiment, and a method of mounting of the battery unit 7 to the electronic cassette 4.

As shown in FIG. 5, a gate line driver 30 is disposed on the scanning control board 23 on which the scan signal control circuit 23A is mounted, and a signal processing section 31 is disposed on the signal processing board 24 on which the signal detection circuit 24A is mounted. The respective scan lines 17 are connected to the gate line driver 30, and the respective signal lines 18 are connected to the signal processing section 31.

An image memory 32, a cassette control section 33 and a wireless communications section 34 are also provided inside the casing 10 of the electronic cassette 4.

The TFT switches 15 of the board 13A are sequentially turned on, row by row, by signals supplied through the scan lines 17 from the gate line driver 30. Charges read out by the TFT switches 15 that have been turned on are propagated through the signal lines 18 and inputted to the signal processing section 31. Thus, the charges are sequentially read out row by row, and a two-dimensional radiation image may be acquired.

Although not shown in the drawings, the signal processing section 31 is provided with an amplification circuit and a sample and hold circuit for each of the signal lines 18. The amplification circuits amplify the inputted electronic signals. After the electronic signals that have been propagated through the respective signal lines 18 are amplified by the amplification circuits, the amplified signals are retained in the sample and hold circuits. At the output side of the sample and hold circuits, a multiplexer and an analog-to-digital (A/D) converter are connected in this order. The electronic signals retained in the respective sample and hold circuits are sequentially (serially) inputted to the multiplexer, and are converted to digital image data by the A/D converter.

The image memory 32 is connected to the signal processing section 31, and the image data outputted from the A/D converter of the signal processing section 31 is sequentially stored in the image memory 32. The image memory 32 has a storage capacity capable of storing a predetermined number of frames of image data. Each time a radiographic image is captured, image data obtained by the imaging is sequentially stored in the image memory 32.

The image memory 32 is connected to the cassette control section 33. The cassette control section 33 includes a microcomputer, and is provided with a central processing unit (CPU) 33A, a memory 33B including a read-only memory (ROM) and random access memory (RAM) that serve as memory media, and a non-volatile storage section 33C formed of flash memory or the like. The cassette control section 33 collectively controls overall operations of the electronic cassette 4.

The wireless communications section 34 is connected to the cassette control section 33. The wireless communications section 34 complies with wireless LAN (local area network) standards, typified by IEEE (Institute of Electrical and Electronics Engineers) standards 802.11 a/b/g and the like. The wireless communications section 34 controls transfers of various kinds of information between the cassette control section 33 and external equipment by wireless communications. The cassette control section 33 is capable of wireless communications with an external equipment such as the console 2 and the like via the wireless communications section 34, and may exchange various kinds of information with the console 2 and the like.

The electronic cassette 4 is provided with a detection section 35 and a continuous imaging allowability determination section 36. The detection section 35 detects whether an external unit such as the battery unit 7 or the like is connected to the connection portion 12. The continuous imaging allowability determination section 36 performs control to allow or prohibit continuous imaging (video imaging in the present exemplary embodiment) in accordance with detection results from the detection section 35. The detection section 35 monitors connection states of the connection portion 12 at intervals of a predetermined duration, generates signals representing the connection states, and sends the signals to the continuous imaging allowability determination section 36. The continuous imaging allowability determination section 36 decides whether to allow or prohibit continuous imaging on the basis of the signals received from the detection section 35, generates signals representing whether continuous imaging is allowed or prohibited, and sends these signals to the cassette control section 33. In the present exemplary embodiment, the detection section 35 and the continuous imaging allowability determination section 36 are embodied by software executed by the CPU 33A, but this is not limiting and they may be embodied by hardware.

The various circuits and various devices of the electronic cassette 4 (the gate line driver 30, the signal processing section 31, the image memory 32, the cassette control section 33, the wireless communications section 34, etc.) are operated by power supplied through the connection portion 12.

The electronic cassette 4 according to the first exemplary embodiment assures enclosure, which is a necessary requirement of the electronic cassette, and is provided with a heat dissipation mechanism that dissipates heat generated by the electronic circuits of the radiation detector 13 (the scan signal control circuit 23A, the signal detection circuit 24A, etc.).

That is, in the electronic cassette 4 according to the first exemplary embodiment, the battery retention portion 11 that mountably and detachably retains the battery unit 7 is provided at an outer periphery portion of the casing 10, as shown in FIG. 4. The heat conduction portion 11A of the battery retention portion 11 is in contact with the electronic circuits of the radiation detector 13 (to be specific, the signal processing board 24 and suchlike at which the electronic circuits are mounted). Therefore, the battery unit 7 and the electronic circuits are thermally connected via the battery retention portion 11, and heat from the electronic circuits is absorbed by the battery unit 7. Thus, the heat dissipation mechanism of the electronic cassette 4 is embodied, and heat from inside the casing 10 may be effectively dissipated.

In the present exemplary embodiment, the battery retention portion 11 includes the heat conduction portion 11A, and the scanning control board 23 and signal processing board 24 are covered with insulators, but this is not limiting. Rather than the battery retention portion 11 being formed of or covered with an insulator and the heat conduction portion 11A being provided, the scanning control board 23 and signal processing board 24 may be formed of materials with high thermal conductivity.

In the present exemplary embodiment, an example in which image data is sent from the electronic cassette 4 to the console 2 by wireless communications is described, but this is not limiting. The electronic cassette 4 and console 2 may be connected by a cable and the image data sent by communications by wire, or the electronic cassette 4 may be placed on the console 2 for the console 2 to read the image data from the electronic cassette 4.

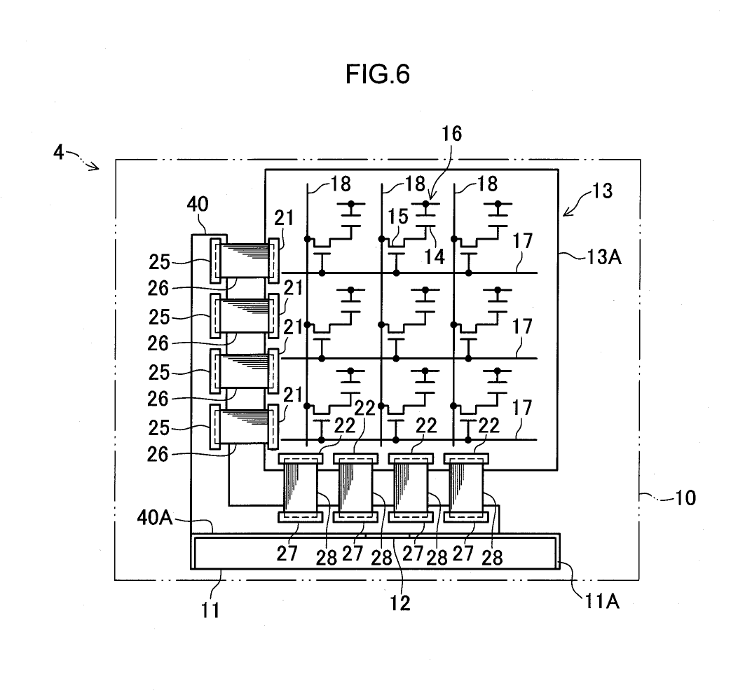

FIG. 6 is a schematic plan view of a constitution in which the scanning control board 23 and the signal processing board 24 are formed integrally in the electronic cassette 4 according to the present exemplary embodiment.

As shown in FIG. 6, in order to enhance the effect of the battery retention portion 11 absorbing heat from the electronic circuits of the radiation detector 13, the scanning control board 23 and signal processing board 24 may be integrally formed as a board 40, as described below. In the electronic cassette 4, if a metallic film with excellent thermal conductivity is provided on this board 40, the battery retention portion 11 may absorb heat more effectively.

### Second Exemplary Embodiment

As a second exemplary embodiment, a battery unit 41 that is provided with both a power supply source 44 and a THERMOMEMORY (trademark) 45, which is a heat-absorbing material, is described. The THERMOMEMORY 45 is formed of a material that absorbs energy in a phase change of a substance (the heat of fusion or heat of solidification), and is employed as a cooling material for electronic equipment. A metal with a high heat capacity may be employed as the THERMOMEMORY 45.

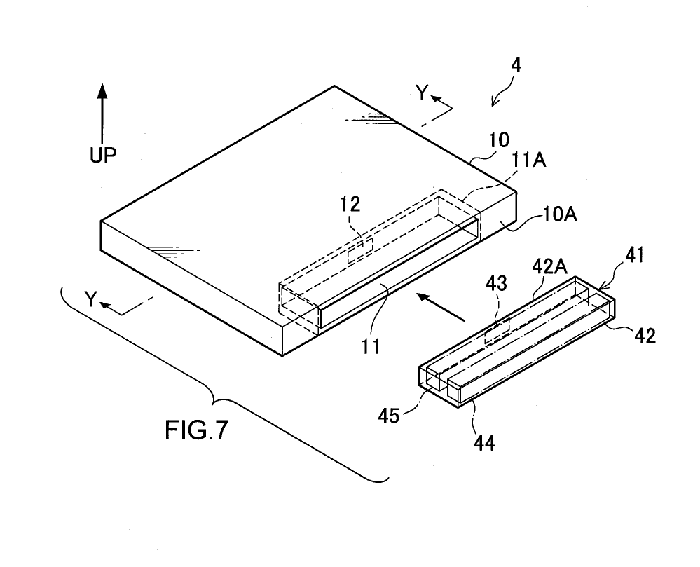

FIG. 7 is a schematic perspective view of the electronic cassette 4 and the battery unit 41 in accordance with the second exemplary embodiment.

As shown in FIG. 7, the battery unit 41 is provided with a casing 42, and the power supply source 44 and THERMOMEMORY 45 and the like are accommodated inside the casing 42. The power supply source 44 and the THERMOMEMORY 45 are each formed in a long, narrow shape. Thus, when the battery unit 41 is retained at the battery retention portion 11, the THERMOMEMORY 45 is arranged so as to be disposed at the connection portion 12 side of the electronic cassette 4, in parallel with the electronic cassette 4.

A connection portion 43 is provided at a side face 42A of the casing 42. The connection portion 43 includes a connection terminal to be connected to the connection portion 12 of the electronic cassette 4. In a state in which the battery unit 41 is retained at the battery retention portion 11, the connection portion 43 of the battery unit 41 is connected to the connection portion 12 of the electronic cassette 4. Thus, power is supplied from the battery unit 41 to the electronic cassette 4 via the respective connection portions 12 and 43.

According to the second exemplary embodiment, when the battery unit 41 is retained at the battery retention portion 11, the THERMOMEMORY 45 absorbs heat generated by the electronic circuits of the radiation detector 13, which is a heat-generating body of the electronic cassette 4. Thus, heat from inside the casing 10 may be effectively dissipated.

In the battery unit 41 according to the second exemplary embodiment, a fan, which is a heat extraction unit, may be provided instead of the THERMOMEMORY 45. The fan may be disposed to efficiently utilize a space in which the THERMOMEMORY 45 would be disposed. Thus, by the fan cooling the electronic circuits of the radiation detector 13 that is the heat-generating body of the electronic cassette 4, heat from inside the casing 10 may be effectively dissipated.

Further, in the battery unit 41 according to the second exemplary embodiment, a Peltier device may be provided instead of the THERMOMEMORY 45. The Peltier device may be disposed to efficiently utilize the space in which the THERMOMEMORY 45 would be disposed. Thus, by the Peltier device cooling the electronic circuits of the radiation detector 13 that is the heat-generating body of the electronic cassette 4, heat from inside the casing 10 may be effectively dissipated.

### Third Exemplary Embodiment

As a third exemplary embodiment, the electronic cassette 4 is described with an electricity supply unit 47 being retained at the battery retention portion 11 instead of the battery unit 41. In the third exemplary embodiment, another component, for example, a THERMOMEMORY 50 as described above, is disposed in the space in which the power supply source 44 would be retained. Thus, a new function (for example, a cooling function) may be added to the electronic cassette 4. In the present exemplary embodiment, the electricity supply unit is provided with a power cable and is structured to be mountable and detachable at the electronic cassette, and is a unit that supplies electricity to the electronic cassette through this power cable.

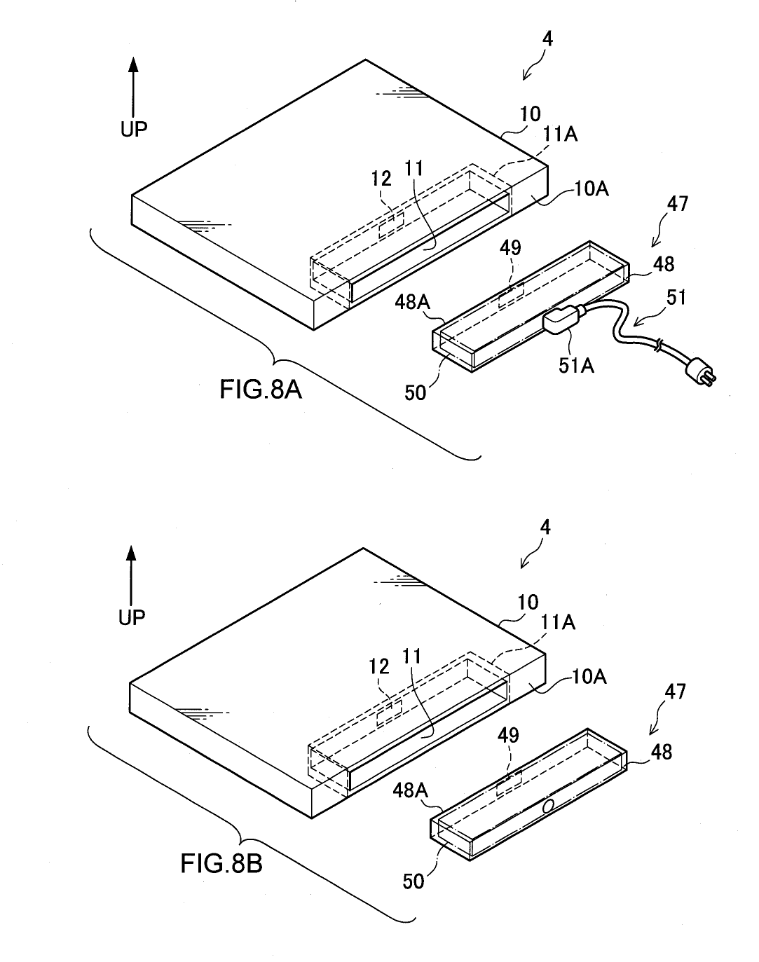

FIG. 8A and FIG. 8B are schematic perspective views of the electronic cassette 4 and electricity supply unit 47 according to the third exemplary embodiment. FIG. 8A is a diagram showing a state in which a power cable 51 is connected to the electricity supply unit 47, and FIG. 8B is a diagram showing a state in which the power cable 51 is not connected to the electricity supply unit 47.

As shown in FIG. 8A and FIG. 8B, the electricity supply unit 47 of the electronic cassette 4 according to the third exemplary embodiment is provided with a casing 48. The THERMOMEMORY 50, a plug 51A of the power cable 51, and wiring and the like are accommodated inside the casing 48. The electricity supply unit 47 is not internally provided with a power supply source. Thus, space inside the casing 48 may be effectively utilized and the THERMOMEMORY 50 may be formed in substantially the same shape as the battery unit 41.

A connection portion 49 is provided at a side face 48A of the casing 48. The connection portion 49 includes a connection terminal to be connected to the connection portion 12 of the electronic cassette 4. In a state in which the electricity supply unit 47 is retained at the battery retention portion 11, the connection portion 49 of the electricity supply unit 47 is connected to the connection portion 12 of the electronic cassette 4. Thus, power is supplied from the electricity supply unit 47 to the electronic cassette 4 via the respective connection portions 12 and 49.

According to the third exemplary embodiment, instead of the power supply source 44 being provided, the THERMOMEMORY 50 is added to efficiently utilize the space in which the power supply source 44 would be disposed. Thus, the THERMOMEMORY 50 is formed to be the same size as the power supply source 44. Therefore, the THERMOMEMORY 50 may absorb heat generated by the electronic circuits of the radiation detector 13 that is the heat-generating body of the electronic cassette 4 without causing an increase in size of the electricity supply unit 47 (and thus the electronic cassette 4). Thus, heat from inside the casing 10 may be effectively dissipated.

In the electricity supply unit 47 according to the third exemplary embodiment, a fan, which is a heat extraction unit, may be provided instead of the THERMOMEMORY 50. The fan may be disposed to efficiently utilize the space in which the THERMOMEMORY 50 would be disposed. Thus, by the fan cooling the electronic circuits of the radiation detector 13 that is the heat-generating body of the electronic cassette 4, heat from inside the casing 10 may be effectively dissipated.

Further, in the electricity supply unit 47 according to the third exemplary embodiment, a Peltier device may be provided instead of the THERMOMEMORY 50. The Peltier device may be disposed to efficiently utilize the space in which the THERMOMEMORY 50 would be disposed. Thus, by the Peltier device cooling the electronic circuits of the radiation detector 13 that is the heat-generating body of the electronic cassette 4, heat from inside the casing 10 may be effectively dissipated.

### Fourth Exemplary Embodiment

As a fourth exemplary embodiment, the electronic cassette 4 is described with an electricity supply unit 55 being provided. The electricity supply unit 55 is equipped with a fan 58 that is a heat extraction unit.

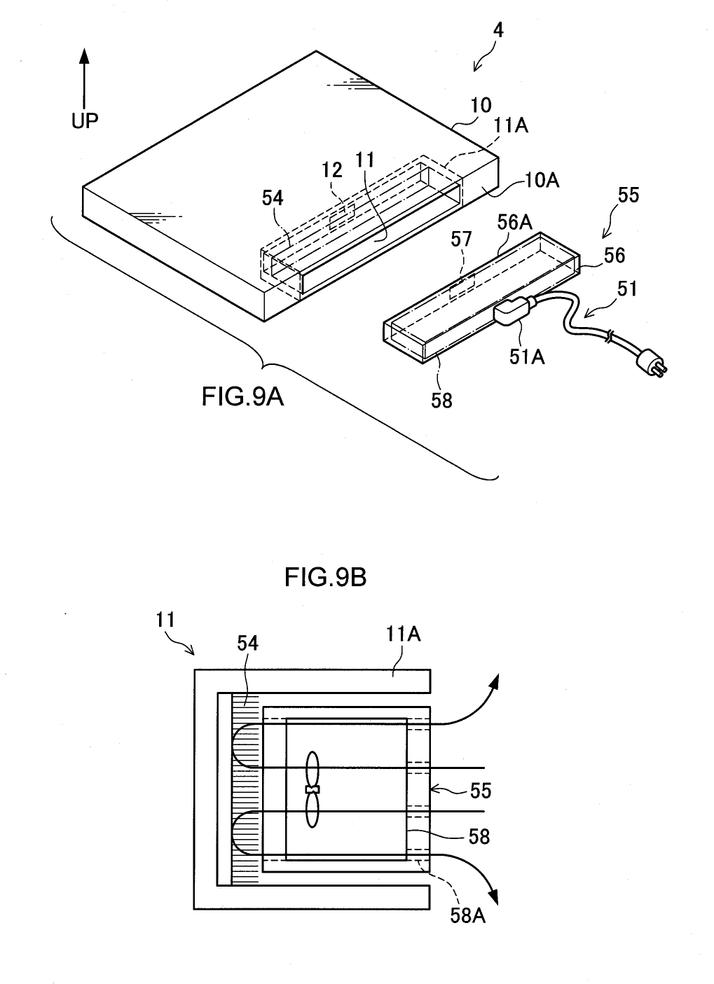

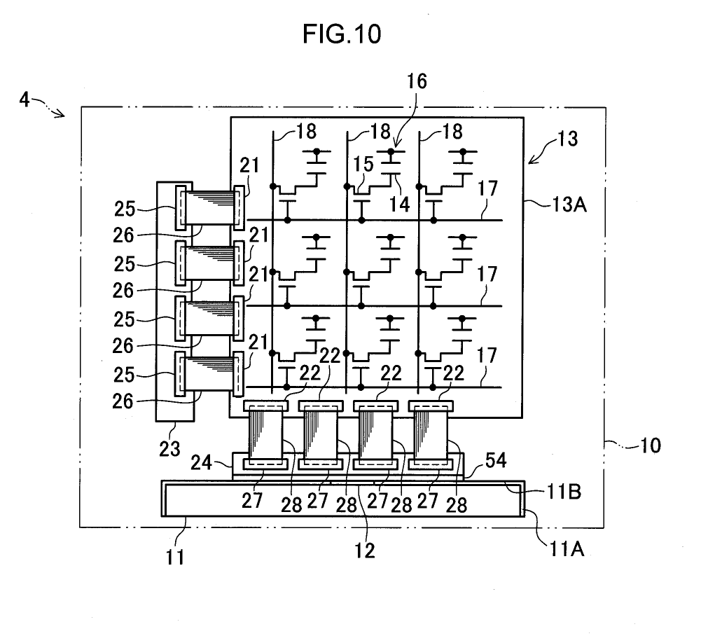

FIG. 9A is a schematic perspective view of the electronic cassette 4 and the electricity supply unit 55 according to the fourth exemplary embodiment. FIG. 9B is a schematic side view for describing a cooling mechanism of the electronic cassette 4 and electricity supply unit 55 according to the fourth exemplary embodiment. FIG. 10 is a diagram showing a schematic plan view of the electronic cassette 4 according to the fourth exemplary embodiment.

As shown in FIG. 9A, FIG. 9B and FIG. 10, a heat sink 54 is provided at an inner side face 11B of the battery retention portion 11 of the electronic cassette 4 (a side face at the side that is closer to the electricity supply unit 55).

The electricity supply unit 55 is provided with a casing 56, and the fan 58 and the like are accommodated inside the casing 56. A connection portion 57 is provided at a side face 56A of the casing 56. The connection portion 57 includes a connection terminal to be connected to the connection portion 12 of the electronic cassette 4. In a state in which the electricity supply unit 55 is retained at the battery retention portion 11, the connection portion 57 of the electricity supply unit 55 is connected to the connection portion 12 of the electronic cassette 4. Thus, power is supplied from the electricity supply unit 55 to the electronic cassette 4 via the respective connection portions 12 and 57.

In the state in which the electricity supply unit 55 is retained at the battery retention portion 11 of the electronic cassette 4, due to the blowing of the fan 58, air flows in through some of communication holes 58A of the electricity supply unit 55, passes over the heat sink 54, and flows out again through some of the communication holes 58A of the electricity supply unit 55. Thus, the heat sink 54 is cooled, and heat is absorbed by the heat sink 54.

According to the fourth exemplary embodiment, instead of the power supply source 44 being provided, the fan 58 is added to efficiently utilize the space in which the power supply source 44 would be disposed. Therefore, the heat sink 54 may absorb heat generated by the electronic circuits of the radiation detector 13 that is the heat-generating body of the electronic cassette 4 without causing an increase in size of the electricity supply unit 55 (and thus the electronic cassette 4). Thus, heat from inside the casing 10 of the electronic cassette 4 may be effectively dissipated.

A structure is possible in which the heat sink 54 is not provided in the battery retention portion 11 of the electronic cassette 4 but the interior of the casing 10 of the electronic cassette 4 is still cooled by the fan 58 of the electricity supply unit 55. In such a case, it is desirable if a structure that allows air blown by the fan 58 to escape to the outside is provided.

### Fifth Exemplary Embodiment

As a fifth exemplary embodiment, the electronic cassette 4 is described as including an electricity supply unit 61. The electricity supply unit 61 is provided with a THERMOMEMORY 64 that is a heat absorbing material.

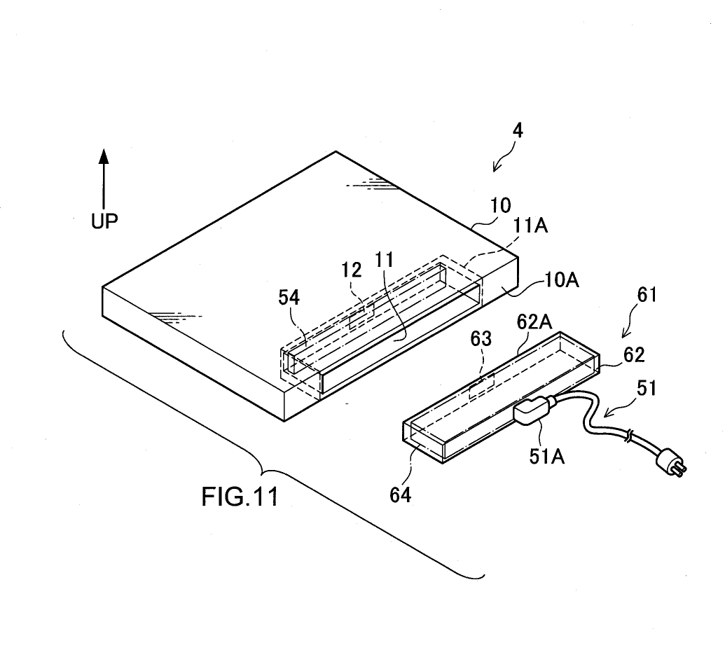

FIG. 11 is a schematic perspective view of the electronic cassette 4 and the electricity supply unit 61 according to the fifth exemplary embodiment.

As shown in FIG. 11 (see also FIG. 10), the heat sink 54 is disposed at the inner side face 11B of the battery retention portion 11 of the electronic cassette 4 (the side face at the side that is closer to the electricity supply unit 61).

The electricity supply unit 61 is provided with a casing 62, and the THERMOMEMORY 64 and the like are accommodated inside the casing 62. A connection portion 63 is provided at a side face 62A of the casing 62. The connection portion 63 includes a connection terminal to be connected to the connection portion 12 of the electronic cassette 4. In the state in which the electricity supply unit 61 is retained at the battery retention portion 11, the connection portion 63 of the electricity supply unit 61 is connected to the connection portion 12 of the electronic cassette 4. Thus, power is supplied from the electricity supply unit 61 to the electronic cassette 4 via the respective connection portions 12 and 63.

In the state in which the electricity supply unit 61 is retained at the battery retention portion 11 of the electronic cassette 4, heat generated by the electronic circuits of the radiation detector 13 is absorbed by the heat sink 54, and is then absorbed by the THERMOMEMORY 64.

According to the fifth exemplary embodiment, instead of the power supply source 44 being provided, the THERMOMEMORY 64 is added to efficiently utilize the space in which the power supply source 44 would be disposed. Therefore, the heat sink 54 and the THERMOMEMORY 64 may absorb heat generated by the electronic circuits of the radiation detector 13 that is the heat-generating body of the electronic cassette 4 without causing an increase in size of the electricity supply unit 61 (and thus the electronic cassette 4). Thus, heat from inside the casing 10 of the electronic cassette 4 may be effectively dissipated.

### Sixth Exemplary Embodiment

As a sixth exemplary embodiment, another example of the electronic cassette 4 is described, in which a heat sink 69 is provided at the battery retention portion 11 and both the power supply source 44 and fans 74 that are a heat extraction unit are provided at a battery unit 70.

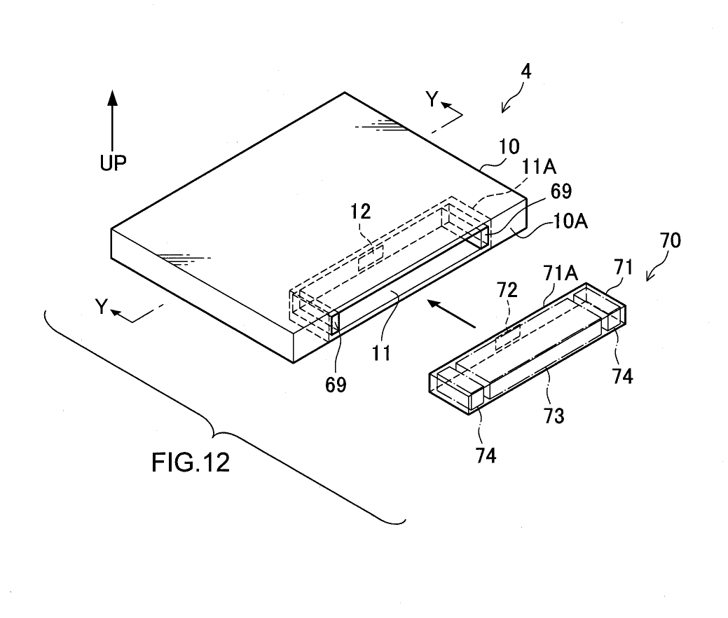

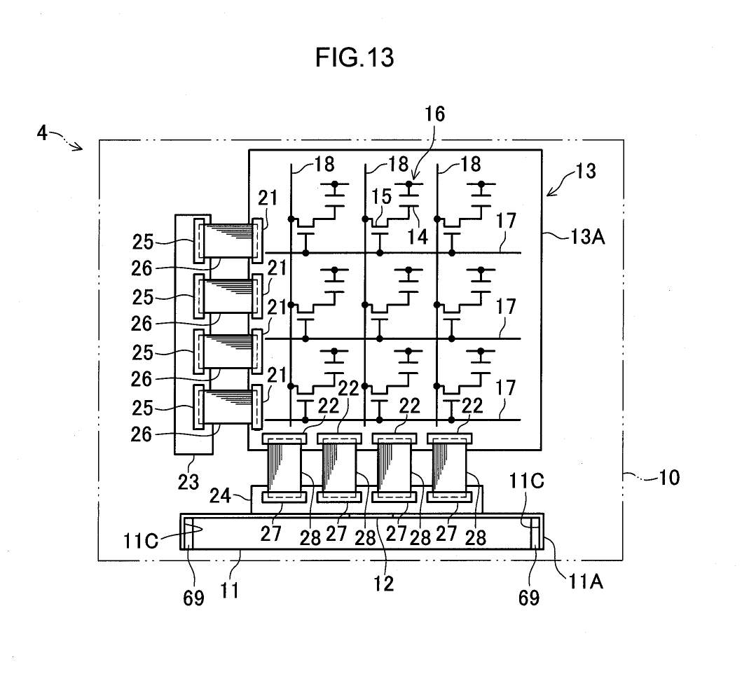

FIG. 12 is a schematic perspective view of the electronic cassette 4 according to the sixth exemplary embodiment. FIG. 13 is a diagram showing a schematic plan view of the electronic cassette 4 according to the sixth equipment.

As shown in FIG. 12 and FIG. 13, the battery retention portion 11 of the electronic cassette 4 is formed in a cuboid shape, and the heat sink 69 is provided at an inside face 11C at each of the two ends of the battery retention portion 11 (the side faces at the side closer to the electricity supply unit 55).

The battery unit 70 is provided with a cuboid casing 71 with the same shape as the interior shape of the battery retention portion 11. The fans 74 and the like are accommodated at the two end sides of the interior of the casing 71. A power supply source 73 is disposed at a central portion of the interior of the casing 71 so as to be surrounded by the plural fans 74. A connection portion 72 is provided at a side face 71 A of the casing 71. The connection portion 72 includes a connection terminal to be connected to the connection portion 12 of the electronic cassette 4. In the state in which the battery unit 70 is retained at the battery retention portion 11, the connection portion 72 of the battery unit 70 is connected to the connection portion 12 of the electronic cassette 4. Thus, power is supplied from the battery unit 70 to the electronic cassette 4 via the respective connection portions 12 and 72.

Here, by a mechanism with the same operation as the cooling mechanism described in the fourth exemplary embodiment, in the state in which the battery unit 70 is retained at the battery retention portion 11 of the electronic cassette 4, the heat sinks 69 are cooled by air blown from the fans 74. Thus, heat generated by the electronic circuits that are the heat-generating body is dissipated.

According to the sixth exemplary embodiment, both the power supply source 44 and the fans 74 are provided inside the battery unit 70. Therefore, the heat sinks 69 may absorb heat generated by the electronic circuits of the radiation detector 13 that is the heat-generating body of the electronic cassette 4 without causing an increase in size of the battery unit 70 (and thus the electronic cassette 4). Thus, heat from inside the casing 10 of the electronic cassette 4 may be effectively dissipated.

A structure is possible in which the heat sinks 69 are not provided in the battery retention portion 11 of the electronic cassette 4 but the interior of the casing 10 of the electronic cassette 4 is still cooled by the fans 74 of the battery unit 70. In such a case, it is desirable if a structure that allows air blown by the fans 74 to escape to the outside is provided.

In the exemplary embodiments described above, cases in which the boards at which the various electronic circuits are mounted are employed as the heat-generating body of the electronic cassette 4 are described. However, the present invention is not limited thus. Modes in which the electronic circuits themselves are employed as the heat-generating body are possible. As examples thereof, modes such as the following may be illustrated: a mode in which upper faces or the like of electronic components with large heat generation amounts (for example, transistors, amplifiers, etc.) in these electronic circuits are put into direct contact with the retention portion; a mode in which the electronic circuits are constituted as semiconductor chips and upper faces or the like of the semiconductor chips are put into direct contact with the retention portion; and the like.

### Seventh Exemplary Embodiment

As a seventh exemplary embodiment, the electronic cassette 4 is described with a battery retention portion 11D being provided at a rear face 10C of the casing 10 and a battery unit 80 being retained at the rear face side of the casing 10.

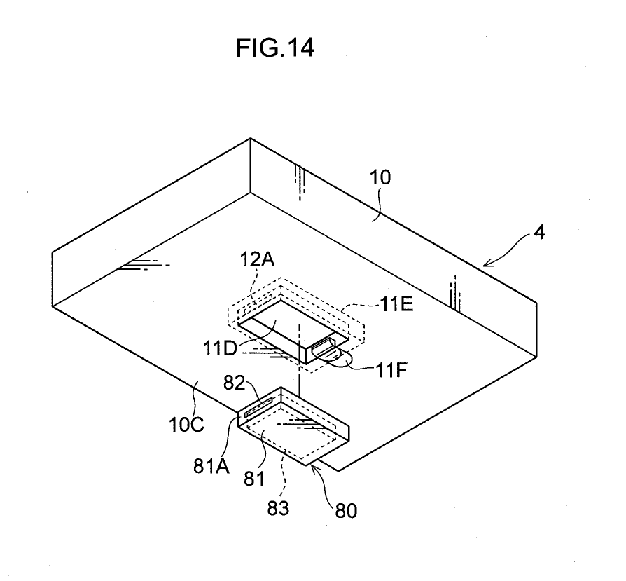

FIG. 14 is a schematic perspective view of the electronic cassette 4 and the battery unit 80 in accordance with the seventh exemplary embodiment.

The casing 10 is a monocoque structure (a laminated structure for which carbon fiber is a desirable material). In order to assure strength of the casing 10, as shown in FIG. 14, the battery retention portion 11D is provided as a recess with a minimum opening area at a central portion of the opposite side (the rear face 10C) of the casing 10 from the side at which the x-rays are incident. The battery retention portion 11D is provided with a heat conduction portion 11E that is formed of a material with excellent thermal conductivity. The battery unit 80 and the heat-generating body of the electronic cassette 4 are in contact via the heat conduction portion 11E. Similarly to the heat conduction portion 11A described above, the material forming the heat conduction portion 11E is, for example, copper, gold, silver, aluminium, a magnesium alloy or the like. A connection portion 12A is provided at an inner surface of the battery retention portion 11D. The connection portion 12A includes a connection terminal for connection with the battery unit 80.

The battery unit 80 is provided with a casing 81 in the shape of a board with the same shape as the interior shape of the battery retention portion 11D. A power supply source 83 and the like are accommodated inside the casing 81. An anchoring portion 11F for anchoring the battery unit 80 is provided in the battery retention portion 11D. The battery unit 80 is anchored at the anchoring portion 11F and thus is retained in the battery retention portion 11D. A connection portion 82 is provided at a side face 81A of the casing 81. The connection portion 82 includes a connection terminal to be connected with the connection portion 12A of the electronic cassette 4. In the state in which the battery unit 80 is retained in the battery retention portion 11D, the connection portion 82 of the battery unit 80 is connected with the connection portion 12A of the electronic cassette 4. Thus, power is supplied from the battery unit 80 to the electronic cassette 4 via the respective connection portions 12A and 82.

In the electronic cassette 4 according to the seventh exemplary embodiment, the battery retention portion 11D that mountably and detachably retains the battery unit 7 is provided at the rear face 10C of the casing 10. Thus, the heat conduction portion 11E of the battery retention portion 11D is in contact with the electronic circuits of the radiation detector 13 (specifically, the signal processing board 24 at which the electronic circuits are mounted and the like). Therefore, the battery unit 7 and the electronic circuits are thermally connected via the battery retention portion 11D, and heat from the electronic circuits is absorbed at the battery unit 7. Thus, the heat dissipation mechanism of the electronic cassette 4 is embodied, and heat from inside the electronic cassette 4 may be effectively dissipated.

In the battery unit 80 according to the seventh exemplary embodiment, a THERMOMEMORY, a fan or a Peltier device may be provided inside the casing 81. Thus, by the THERMOMEMORY, fan or Peltier device cooling the electronic circuits of the radiation detector 13 that is the heat-generating body of the electronic cassette 4, heat from the interior of the electronic cassette 4 may be effectively dissipated.

In the seventh exemplary embodiment, instead of the battery unit 80 with the power supply source 83 thereinside being installed at the battery retention portion 11D of the electronic cassette 4, an electricity supply unit including a power cable and a cooling section may be installed. The cooling section is the above-mentioned THERMOMEMORY, fan, Peltier device or the like. Thus, the cooling section of the electricity supply unit may cool the electronic circuits of the radiation detector 13 that is the heat-generating body of the electronic cassette 4, and heat from the interior of the electronic cassette 4 may be effectively dissipated.

Further, in the seventh exemplary embodiment, a heat-absorbing material such as a heat sink or the like may be provided at the battery retention portion 11D of the electronic cassette 4. Thus, the heat-absorbing material of the electronic cassette 4 may cool the electronic circuits of the radiation detector 13 that is the heat-generating body of the electronic cassette 4, and heat from the interior of the electronic cassette 4 may be effectively dissipated.

### Eighth Exemplary Embodiment

As an eighth exemplary embodiment, the electronic cassette 4 is described as carrying out continuous imaging allowability control processing. When images are to be imaged, this processing determines whether or not a power cable is connected to the electronic cassette 4 via the connection portion 12 and power is being supplied through the power cable. On the basis of the determination result, the processing controls to allow or prohibit continuous imaging, such that continuous imaging (video imaging) is allowed if power is being supplied through the power cable.

Either a battery unit or an electricity supply unit may be installed at the battery retention portion 11 of the electronic cassette 4. During imaging, heat generation amounts are larger when continuous imaging is performed than when still images are captured. Consequently, while the dissipation of heat generated by still image capture may be sufficient and image quality may not deteriorate, the dissipation of heat generated by continuous imaging may be insufficient and image quality may deteriorate.

Therefore, the electronic cassette 4 according to the present exemplary embodiment executes continuous imaging allowability control processing that prohibits continuous imaging when the electronic cassette is equipped with a battery unit, because of the possibility that cooling may be insufficient for heat generated by the battery and the like, and that allows continuous imaging when the electronic cassette is equipped with an electricity supply unit, because a power supply source is not provided inside the electricity supply unit and cooling of the electronic cassette 4 is sufficient.

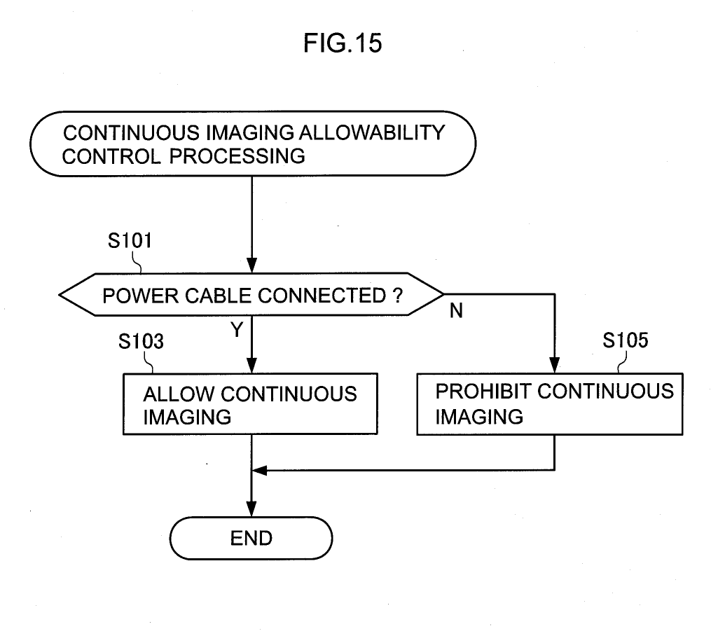

Below, operation of the electronic cassette 4 when this continuous imaging allowability control processing is being executed is described with reference to FIG. 15. FIG. 15 is a flowchart showing a flow of processing of a continuous imaging allowability control processing program that is executed by the CPU 33A of the electronic cassette 4 at intervals of a predetermined duration. This program is memorized in advance in a predetermined region of the storage section 33C that is a storage medium.

First, in step S101, the CPU 33A (see FIG. 5) determines whether or not a power cable is connected to the electronic cassette 4. The detection section 35 sends signals, indicating whether or not an electricity supply unit with a power cable is connected, to the continuous imaging allowability determination section 36 at intervals of the predetermined duration. The CPU 33A controls the continuous imaging allowability determination section 36 so as to determine whether or not an electricity supply unit with a power cable is connected. Alternatively, the detection section 35 may send signals indicating that an electricity supply unit with a power cable is connected to the connection portion 12 of the electronic cassette 4 only when an electricity supply unit with a power cable is connected.

If it is determined in step S101 that a power cable is connected, then in step S103 the CPU 33A allows video imaging (continuous imaging). On the other hand, if it is not determined that a power cable is connected in step S101, then in step S105 the CPU 33A prohibits video imaging (continuous imaging).

In the present exemplary embodiment, an example in which continuous imaging is prohibited if it is determined that a battery unit is installed at the electronic cassette 4 is described. However, if the battery unit is equipped with a high-precision cooling function, continuous imaging may be allowed just as when an electricity supply unit is installed.

According to the eighth exemplary embodiment, if connections of the battery unit 7 to the battery retention portion 11 and removals of the battery unit 7 are detected, continuous imaging is allowed when it is detected that the battery unit 7 is connected to the battery retention portion 11 and continuous imaging is prohibited when it is detected that the battery unit 7 is removed from the battery retention portion 11. Therefore, continuous imaging is prohibited when no power cable is connected, and an effect is provided in that heat from the inside may be discharged without causing an increase in size of the device.

### Ninth Exemplary Embodiment

As a ninth exemplary embodiment, a radiographic image capture system 1A is described in which the radiographic image capture system 1 according to any of the above-described first, second and seventh exemplary embodiments is further provided with a charging device 90 that charges and cools the battery unit 7, 41 or 80.

The electronic cassette 4 according to any of the above-described first, second and seventh exemplary embodiments receives the supply of power and is cooled when the battery unit 7, 41 or 80 is installed therein. However, if the battery unit 7, 41 or 80 is used continuously, the battery unit 7, 41 or 80 must be charged again after having supplied its power to the electronic cassette 4 and/or must be cooled after having cooled the electronic cassette 4. Therefore, the radiographic image capture system 1A is provided with the charging device 90 that provides charging and cooling to the battery unit 7, 41 or 80.

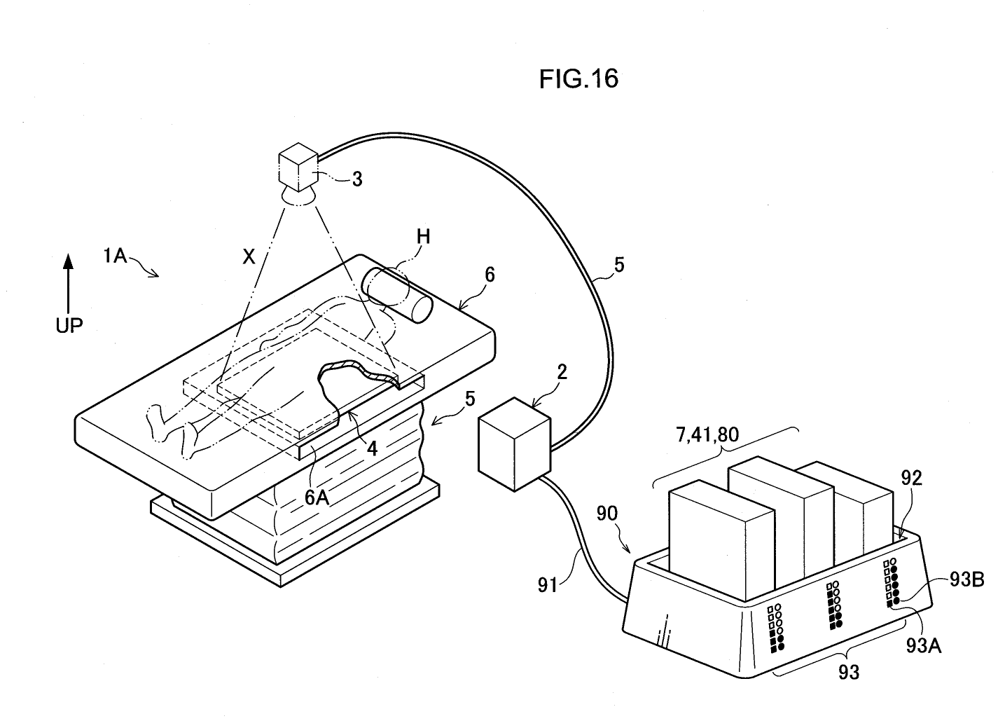

FIG. 16 is a schematic perspective view of the radiographic image capture system 1A according to the ninth exemplary embodiment.

As shown in FIG. 16, the radiographic image capture system 1A according to the ninth exemplary embodiment is equipped with the charging device 90 that performs charging of the battery unit 7, 41 or 80 that supplies power to the electronic cassette 4. The charging device 90 is connected to the console 2 via an electric lamp line 91. When the charging device 90 is connected via the electric lamp line 91, the console 2 communicates with the charging device 90 over the electric lamp line. Communications over electric lamp line are communications that use a power line as a communications circuit.

The charging device 90 is provided with a recessed accommodation portion 92 inside which each battery unit 7, 41 or 80 is installed. The accommodation portion 92 includes a connection portion that is not shown in the drawings. When this connection portion is connected to the connection portion 9, 43 or 82 of the battery unit 7, 41 or 80 accommodated inside the accommodation portion 92, power is supplied from the charging device 90 to the battery unit 7, 41 or 80 and charging of the battery unit 7, 41 or 80 is implemented.

The charging device 90 is further provided with a cooling section inside the accommodation portion 92, which is not shown in the drawings. The cooling section is disposed close to the battery unit 7, 41 or 80 accommodated inside the accommodation portion 92 when the battery unit 7, 41 or 80 is installed. The cooling section is, for example, a heat dissipation fan. The charging device 90 is not limited in power source capacity, and a Peltier device may be used as the cooling section. Alternatively, the accommodation portion 92 may be filled with a liquid and cooling performed by the liquid. Further, as recited in JP-A No. 2009-290138, atomized alcohol may be used for the cooling. Thus, when the battery unit 7, 41 or 80 is accommodated inside the accommodation portion 92, the battery unit 7, 41 or 80 is cooled by the cooling section.

Moreover, the charging device 90 is provided with an indicator 93 for reporting a remaining current capacity and temperature of each battery unit 7, 41 or 80 accommodated in the accommodation portion 92. The indicator 93 is constituted with a remaining current capacity display portion 93A and a temperature display portion 93B. The remaining current capacity display portion 93A is for reporting a remaining current capacity of the battery unit 7, 41 or 80 accommodated in the accommodation portion 92. The temperature display portion 93B is for reporting a temperature of the same. The remaining current capacity display portion 93A is constituted by plural (for example, six) LEDs, and informs the remaining current capacity in steps by lighting up numbers of the LEDs. Similarly, the temperature display portion 93B is constituted by plural (for example, six) LEDs, and informs the temperature in steps by lighting up numbers of the LEDs.

The console 2 acquires information representing a charging condition (the remaining charge capacity condition) and information representing a cooling condition (the temperature condition) of each battery unit 7, 41 or 80 from the charging device 90 by communicating with the charging device 90 over the electric lamp line. The console 2 informs this information to a user by displaying the information at a display device. Together with this information, whether or not the battery unit may be installed at the electronic cassette 4, an indication of a time when the battery unit 7, 41 or 80 may be installed, or the like may also be reported.

A system of communications between the console 2 and the charging device 90 is not limited to communications by electric lamp line; another system of communications by wire or communications by wireless may be used.

According to the ninth exemplary embodiment, in the state in which the battery unit 7, 41 or 80 is installed at the charging device 90 equipped with the cooling section, cooling may be performed by the cooling section while charging is being performed. Therefore, the charging device 90 and the battery unit 7, 41 or 80 are thermally connected and the battery unit 7, 41 or 80 is caused to dissipate heat. Hence, when the cooled battery unit 7, 41 or 80 is installed at the electronic cassette 4, heat from inside the electronic cassette 4 may be effectively dissipated.

According to a first aspect of the present invention, there is provided a radiographic image capture device including: a radiographic detector that acquires a radiographic image in accordance with incident radiation and that includes a heat-generating body at an inner part thereof; and a retention portion that is provided so as to be in contact with the heat-generating body of the radiographic detector, that detachably retains a power supply portion, and that is thermally conductive.

According to the radiographic image capture device relating to the first aspect of the present invention, a radiographic image is acquired in accordance with incident radiation by the radiographic detector that includes the heat-generating body. In the first aspect of the present invention, the retention portion with thermal conductivity at which the battery unit is mountably/detachably retained is provided so as to touch the heat-generating body of the radiographic detector.

Thus, the power supply portion retained at the retention portion may absorb heat discharged from the heat-generating body of the radiographic detector. As a result, heat from inside the radiographic image capture device may be effectively discharged without an increase in size of the radiographic image capture device being caused.

According to a second aspect of the present invention, in the radiographic image capture device relating to the first aspect of the present invention, the heat-generating body may include an electronic circuit of the radiographic detector, and the retention portion is thermally connected with the electronic circuit. Thus, because a battery unit retained at the retention portion is thermally connected with the electronic circuit(s) of the radiographic detector, the heat from inside may be effectively discharged.

According to a third aspect of the present invention, in the radiographic image capture device relating to the first or second aspect of the present invention, the power supply portion may include a cooling function by providing, at the power supply portion, at least one of a heat storage material that memorizes and preserves a particular temperature or a cooler. Thus, because the cooling function of a battery unit retained at the retention portion absorbs heat discharged from the heat-generating body of the radiographic detector, the heat from inside may be effectively discharged.

According to a fourth aspect of the present invention, in the radiographic image capture device relating to any of the first to third aspects of the present invention, the power supply portion may include one of a battery unit that accommodates a battery thereinside or an electricity supply unit that is provided with a power cable, and may supply power from an external source via the power cable. Thus, the heat from inside may be effectively discharged by the battery unit or electricity supply unit retained at the retention portion.

According to a fifth aspect of the present invention, in the radiographic image capture device relating to the fourth aspect of the present invention, the retention portion may include a heat dissipation portion that is disposed between the retention portion and the battery unit or the electricity supply unit when the retention portion retains the battery unit or the electricity supply unit. Thus, because the heat dissipation portion disposed between the retention portion and the battery unit or electricity supply unit retained at the retention portion dissipates the heat discharged from the heat-generating body of the radiographic detector, the heat from inside may be effectively discharged.

According to a sixth aspect of the present invention, the radiographic image capture device relating to any of the first to fifth aspects of the present invention may further include: a detection unit that detects whether or not the electricity supply unit is connected to the retention portion; and a continuous imaging allowability determination unit that allows continuous imaging if the detection unit detects that the electricity supply unit is connected to the retention portion, and that prohibits continuous imaging if the detection unit does not detect that the electricity supply unit is connected to the retention portion. Thus, continuous imaging may be prohibited if a power cable is not connected, and the heat from inside may be effectively discharged.

According to a seventh aspect of the present invention, there is provided a battery unit including: a retained portion that is retained at a retention portion of a radiographic image capture device including a radiographic detector that acquires a radiographic image in accordance with incident radiation and that includes a heat-generating body at an inner part thereof, and including the retention portion, which is provided so as to be in contact with the heat-generating body of the radiographic detector, which detachably retains a power supply portion, and which is thermally conductive; the power supply portion, which supplies electric power to the radiographic detector when the retained portion is retained at the retention portion; and a cooling section that cools the radiographic image capture device when the retained portion is retained at the retention portion.

According to the battery unit relating to the seventh aspect of the present invention, operation is similar to the invention relating to the first aspect of the present invention. Thus, similarly to the invention relating to the first aspect, the power supply portion retained at the retention portion may dissipate heat discharged from the heat-generating body of the radiographic detector. As a result, the heat from inside may be effectively discharged without an increase in size of the device being caused.

According to an eighth aspect of the present invention, in the battery unit relating to the seventh aspect of the present invention, the cooling section may include at least one of a heat storage material that memorizes and preserves a particular temperature or a cooler. Thus, because one or both of a heat storage material and a cooler of the power supply portion retained at the retention portion absorbs heat discharged from the heat-generating body of the radiographic detector, the heat from inside may be effectively discharged.

According to a ninth aspect of the present invention, there is provided an electricity supply unit including: a retained portion that is retained at a retention portion of a radiographic image capture device including a radiographic detector that acquires a radiographic image in accordance with incident radiation and that includes a heat-generating body at an inner part thereof, and including the retention portion, which is provided so as to be in contact with the heat-generating body of the radiographic detector, which detachably retains a power supply portion, and which is thermally conductive; a power cable that supplies electric power to the radiographic detector if the retained portion is retained at the retention portion; and a cooling section that cools the radiographic image capture device if the retained portion is retained at the retention portion.

According to the electricity supply unit relating to the ninth aspect of the present invention, operation is similar to the invention relating to the first aspect of the present invention. Thus, similarly to the invention relating to the first aspect, the power supply portion retained at the retention portion may dissipate heat discharged from the heat-generating body of the radiographic detector. As a result, the heat from inside may be effectively discharged without an increase in size of the device being caused.

According to a tenth aspect of the present invention, in the electricity supply unit relating to the ninth aspect of the present invention, the cooling section may include at least one of a heat storage material that memorizes and preserves a particular temperature and a cooler. Thus, because one or both of a heat storage material and a cooler of the power supply portion retained at the retention portion absorbs heat discharged from the heat-generating body of the radiographic detector, the heat from inside may be effectively discharged.

A radiographic image capture system relating to an eleventh aspect of the present invention includes a radiographic image capture device according to any of the first to sixth aspects of the present invention and a battery unit according to the seventh or eighth aspect of the present invention.

According to the radiographic image capture system relating to the eleventh aspect of the present invention, operation is similar to the invention relating to the first aspect of the present invention. Thus, similarly to the invention relating to the first aspect, the power supply portion retained at the retention portion may dissipate heat discharged from the heat-generating body of the radiographic detector. As a result, the heat from inside may be effectively discharged without an increase in size of the device being caused.

A radiographic image capture system relating to a twelfth aspect of the present invention may include a radiographic image capture device according to any of the first to sixth aspects of the present invention and an electricity supply unit according to the ninth or tenth aspect of the present invention. Thus, the power supply portion retained at the retention portion may dissipate heat discharged from the heat-generating body of the radiographic detector. As a result, the heat from inside may be effectively discharged without an increase in size of the device being caused.

According to a thirteenth aspect of the present invention, a computer readable medium storing a program causing a computer to execute a processing including: detecting whether or not an electricity supply unit is retained at a retention portion of a radiographic image capture device, wherein the radiographic image capture device includes a radiographic detector that acquires a radiographic image in accordance with incident radiation and that includes a heat-generating body at an inner part thereof, and includes the retention portion, which is provided so as to be in contact with the heat-generating body of the radiographic detector, which detachably retains a power supply portion, and which is thermally conductive, and wherein the electricity supply unit includes a power cable that supplies electric power to the radiographic detector in a state in which the electricity supply unit is retained at the retention portion; if it is detected that the electricity supply unit is retained at the retention portion, allowing continuous imaging; and if it is not detected that the electricity supply unit is retained at the retention portion, prohibiting continuous imaging.

According to the thirteenth aspect of the present invention, a computer may be caused to operate similarly to the invention relating to the first aspect of the present invention. Thus, similarly to the invention relating to the first aspect, the electricity supply unit retained at the retention portion may dissipate heat discharged from the heat-generating body of the radiographic detector. As a result, the heat from inside may be effectively discharged without an increase in size of the device being caused.

According to the present invention, heat inside a radiographic image capture device may be effectively discharged without an increase in size of the radiographic image capture device being caused.

Embodiments of the present invention are described above, but the present invention is not limited to the embodiments as will be clear to those skilled in the art.

What is claimed is:

1. A radiographic image capture device comprising:
a radiographic detector that acquires a radiographic image in accordance with incident radiation and that includes a heat-generating body at an inner part thereof; and
a retention portion that is provided so as to be in contact with the heat-generating body of the radiographic detector, that detachably retains a power supply portion, and that is thermally conductive.

2. The radiographic image capture device according to claim 1, wherein the heat-generating body includes an electronic circuit of the radiographic detector, and the retention portion is thermally connected with the electronic circuit.

3. The radiographic image capture device according to claim 1, wherein the power supply portion includes a cooling function by providing, at the power supply portion, at least one of a heat storage material that memorizes and preserves a particular temperature or a cooler.

4. The radiographic image capture device according to claim 1, wherein the power supply portion includes one of a battery unit that accommodates a battery therein or an electricity supply unit that is provided with a power cable and supplies power from an external source via the power cable.

5. The radiographic image capture device according to claim 4, wherein the retention portion includes a heat dissipation portion that is disposed between the retention portion and the battery unit or the electricity supply unit when the retention portion retains the battery unit or the electricity supply unit.

6. The radiographic image capture device according to claim 1, further comprising:
a detection unit that detects whether or not the electricity supply unit is connected to the retention portion; and
a continuous imaging allowability determination unit that allows continuous imaging if the detection unit detects that the electricity supply unit is connected to the retention portion, and that prohibits continuous imaging if the detection unit does not detect that the electricity supply unit is connected to the retention portion.

7. A battery unit comprising:
a retained portion that is retained at a retention portion of a radiographic image capture device including a radiographic detector that acquires a radiographic image in accordance with incident radiation and that includes a heat-generating body at an inner part thereof, and including the retention portion, which is provided so as to be in contact with the heat-generating body of the radiographic detector, which detachably retains a power supply portion, and which is thermally conductive;
the power supply portion, which supplies electric power to the radiographic detector when the retained portion is retained at the retention portion; and
a cooling section that cools the radiographic image capture device when the retained portion is retained at the retention portion.

8. The battery unit according to claim 7, wherein the cooling section includes at least one of a heat storage material that memorizes and preserves a particular temperature or a cooler.

9. An electricity supply unit comprising:
a retained portion that is retained at a retention portion of a radiographic image capture device including a radiographic detector that acquires a radiographic image in accordance with incident radiation and that includes a heat-generating body at an inner part thereof, and including the retention portion, which is provided so as to be in contact with the heat-generating body of the radiographic detector, which detachably retains a power supply portion, and which is thermally conductive;
a power cable that supplies electric power to the radiographic detector if the retained portion is retained at the retention portion; and
a cooling section that cools the radiographic image capture device if the retained portion is retained at the retention portion.

10. The electricity supply unit according to claim 9, wherein the cooling section includes at least one of a heat storage material that memorizes and preserves a particular temperature or a cooler.

11. A radiographic image capture system comprising:
the radiographic image capture device according to claim 1; and
a battery unit comprising:
a retained portion that is retained at a retention portion of a radiographic image capture device including a radiographic detector that acquires a radiographic image in accordance with incident radiation and that includes a heat-generating body at an inner part thereof, and including the retention portion, which is provided so as to be in contact with the heat-generating body of the radiographic detector, which detachably retains a power supply portion, and which is thermally conductive;
the power supply portion, which supplies electric power to the radiographic detector if the retained portion is retained at the retention portion; and
a cooling section that cools the radiographic image capture device if the retained portion is retained at the retention portion.

12. A radiographic image capture system comprising:
the radiographic image capture device according to claim 1; and
an electricity supply unit comprising:
a retained portion that is retained at a retention portion of a radiographic image capture device including a radiographic detector that acquires a radiographic image in accordance with incident radiation and that includes a heat-generating body at an inner part thereof, and including the retention portion, which is provided so as to be in contact with the heat-generating body of the radiographic detector, which detachably retains a power supply portion, and which is thermally conductive;
a power cable that supplies electric power to the radiographic detector if the retained portion is retained at the retention portion; and
a cooling section that cools the radiographic image capture device if the retained portion is retained at the retention portion.

13. A computer readable medium storing a program causing a computer to execute a processing comprising:
detecting whether or not an electricity supply unit is retained at a retention portion of a radiographic image capture device, wherein the radiographic image capture device includes a radiographic detector that acquires a radiographic image in accordance with incident radiation and that includes a heat-generating body at an inner part thereof, and includes the retention portion, which is provided so as to be in contact with the heat-generating body of the radiographic detector, which detachably retains a power supply portion, and which is thermally conductive, and wherein the electricity supply unit includes a power cable that supplies electric power to the radiographic detector in a state in which the electricity supply unit is retained at the retention portion;
if it is detected that the electricity supply unit is retained at the retention portion, allowing continuous imaging; and
if it is not detected that the electricity supply unit is retained at the retention portion, prohibiting continuous imaging.
